(19) United States
(12) Patent Application Publication
(10) Pub. No.: US 2005/0069032 A1
(43) Pub. Date: Mar. 31, 2005

(54) Analog equalizer

(75) Inventors: Takashi Hirata, Osaka (JP); Toru Iwata, Osaka (JP); Noriaki Takeda, Hyogo (JP)

Correspondence Address: Jack Q. Lever, Jr.;McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/947,382

(22) Filed: Sep. 23, 2004

(30) Foreign Application Priority Data
Sep. 26, 2003 (JP) 2003-334696

(51) Int. Cl. H03K 5/159

(52) U.S. Cl. 375/229

(57) ABSTRACT

An analog equalizer includes a mixer and an analog delay circuit. The mixer mixes an input signal and a delayed signal output from the analog delay circuit to output a mixed signal. The analog delay circuit delays the mixed signal output from the mixer to output a delayed signal.

### CROSS-REFERENCE TO RELATED APPLICATION

This application claims priority under 35 U.S.C. § 119(a) on Japanese Patent Application No. 2003-334696 filed on Sep. 26, 2003, the entire contents of which are hereby incorporated by reference.

### BACKGROUND OF THE INVENTION

1. Field of the Invention

The present invention relates to a semiconductor LSI device and specifically to a receiving circuit.

2. Description of the Prior Art

When a high-speed electric signal is transmitted through a conductive cable, the band of the signal is restricted due to the skin effect, or the like. Accordingly, intersymbol interference (ISI) occurs, so that the signal quality at a signal receiving terminal deteriorates. The deterioration of the signal quality sometimes causes a decrease in the amplitude of the signal. As a result, a digital circuit which determines an input signal as being High or Low, for example, may not determine data, and in such a case, may cause a malfunction. This phenomenon becomes more conspicuous as the length of a cable or the speed of signal transmission increases. In order to remove such phenomenon, it is necessary to equalize a received signal.

JSSC, May 2000, pp. 757-764 discloses an equalizing method which overcomes the above problem, wherein a clock is obtained by a special clock recovery circuit, sampling is performed on a received signal using the obtained clock, and sampled signal sequences are synthesized, whereby the received signal is equalized.

### SUMMARY OF THE INVENTION

However, in this method, sampling of data is performed based on a clock, and therefore, it is necessary to adjust the phase of the receive signal and that of the sampling clock. Thus, a special clock recovery circuit is required. Further, a switch alternates at a high speed in synchronization with the clock, and therefore, there is a possibility that noise occurs in the sampling process.

According to an aspect of the present invention, an analog equalizer comprises a mixer and an analog delay circuit. The mixer mixes an input signal and a delayed signal output from the analog delay circuit to output a mixed signal. The analog delay circuit delays the mixed signal output from the mixer to output a delayed signal.

In the above analog equalizer, the input signal is continuously delayed while the amplitude information of the input signal is retained, whereby an equalizer is readily structured without correcting the phase difference between a sampling clock and the input signal or removing noise generated in sampling.

According to another aspect of the present invention, an analog equalizer comprises an analog delay circuit and a mixer. The analog delay circuit delays an input signal to output a delayed signal. The mixer mixes the input signal and the delayed signal output from the analog delay circuit.

In the above analog equalizer, the input signal is continuously delayed while the amplitude information of the input signal is retained, whereby an equalizer is readily structured without correcting the phase difference between a sampling clock and the input signal or removing noise generated in sampling.

Preferably, the analog equalizer comprises a delay control section. The delay control section controls a delay amount of the analog delay circuit.

In the above analog equalizer, the delay amount of the analog delay circuit is controlled according to the delay control signal, whereby the phase difference caused by wiring delay or gate delay is adjusted.

Preferably, the delay control section outputs a delay control signal according to a predetermined clock. The analog delay circuit controls the delay amount according to the delay control signal output from the delay control section.

In the above analog equalizer, the delay control signal is output based on a clock corresponding to the input signal, whereby the delay amount of the analog delay circuit is adjusted to the transfer rate of the input signal.

Preferably, the delay control section includes a PLL circuit. The PLL circuit includes a delay control signal output section and a voltage controlled oscillator. The delay control signal output section outputs the delay control signal according to a frequency difference or phase difference between the predetermined clock and a clock output from the voltage controlled oscillator. The voltage controlled oscillator adjusts the delay amount according to the delay control signal output from the delay control signal output section to output a clock. The delay amount of the analog delay circuit corresponds to the delay amount of the voltage controlled oscillator.

In the above analog equalizer, the delay control signal is output based on a clock corresponding to the input signal, whereby the delay amount of the analog delay circuit is adjusted to the transfer rate of the input signal. Since the delay amount of the analog delay circuit corresponds to the delay amount of the voltage controlled oscillator, the delay amount of the analog delay circuit can be set readily.

Preferably, the delay control section includes a DLL circuit. The DLL circuit includes a delay control signal output section and a voltage controlled delay circuit. The delay control signal output section outputs the delay control signal according to a phase difference between the predetermined clock and a clock output from the voltage controlled delay circuit. The voltage controlled delay circuit delays the predetermined clock by the delay amount determined according to the delay control signal output from the delay control signal output section. The delay amount of the analog delay circuit corresponds to the delay amount of the voltage controlled delay circuit.

In the above analog equalizer, the delay control signal is output based on a clock corresponding to the input signal, whereby the delay amount of the analog delay circuit is adjusted to the transfer rate of the input signal. Since the delay amount of the analog delay circuit corresponds to the delay amount of the voltage controlled delay circuit, the delay amount of the analog delay circuit can be set readily.

Preferably, the analog equalizer further comprises a matching circuit. The matching circuit matches the amplitudes of signals input to the mixer (e.g., the input signal and the delayed signal).

In the above analog equalizer, the equalizing power of the equalizer can be adjusted without depending on the amplitude of the input signal.

Preferably, the analog equalizer further comprises a matching circuit. The matching circuit matches the amplitude of a signal input to the analog delay circuit and the amplitude of a signal output from the analog delay circuit.

In the above analog equalizer, the delay amount of the analog delay circuit becomes closer to the delay amount of the voltage controlled oscillator (or the voltage controlled delay circuit). With this structure, adjustment of the delay amount of the analog delay circuit can be performed more readily.

The input signal is continuously delayed while the amplitude information of the input signal is retained, whereby an equalizer can readily be structured.

### BRIEF DESCRIPTION OF THE DRAWINGS

FIG. 1 is a block diagram showing the general structure of a reception LSI device according to embodiment 1 of the present invention.

FIG. 2 is a block diagram showing the internal structure of an analog equalizer 9 shown in FIG. 1.

FIG. 3 is a circuit diagram showing the internal structure of a mixer 11 shown in FIG. 2.

FIG. 4 is a block diagram showing the internal structure of an analog delay circuit 12 shown in FIG. 2.

FIG. 5 is a waveform chart which illustrates the variation of input differential signal DIN+, DIN− in the analog equalizer 9.

FIG. 6 is a block diagram showing the internal structure of an analog equalizer 9 according to embodiment 2 of the present invention.

FIG. 7 is a block diagram showing the internal structure of an analog equalizer 9 according to embodiment 3 of the present invention.

FIG. 8 is a block diagram showing the internal structure of an analog equalizer 9 according to embodiment 4 of the present invention.

### DESCRIPTION OF THE PREFERRED EMBODIMENTS

Hereinafter, embodiments of the present invention will be described in detail with reference to the drawings. Throughout the drawings, like or equivalent elements are denoted by like reference numerals, and therefore, descriptions thereof are not repeatedly provided.

(Embodiment 1)

<General Structure of Reception LSI Device>

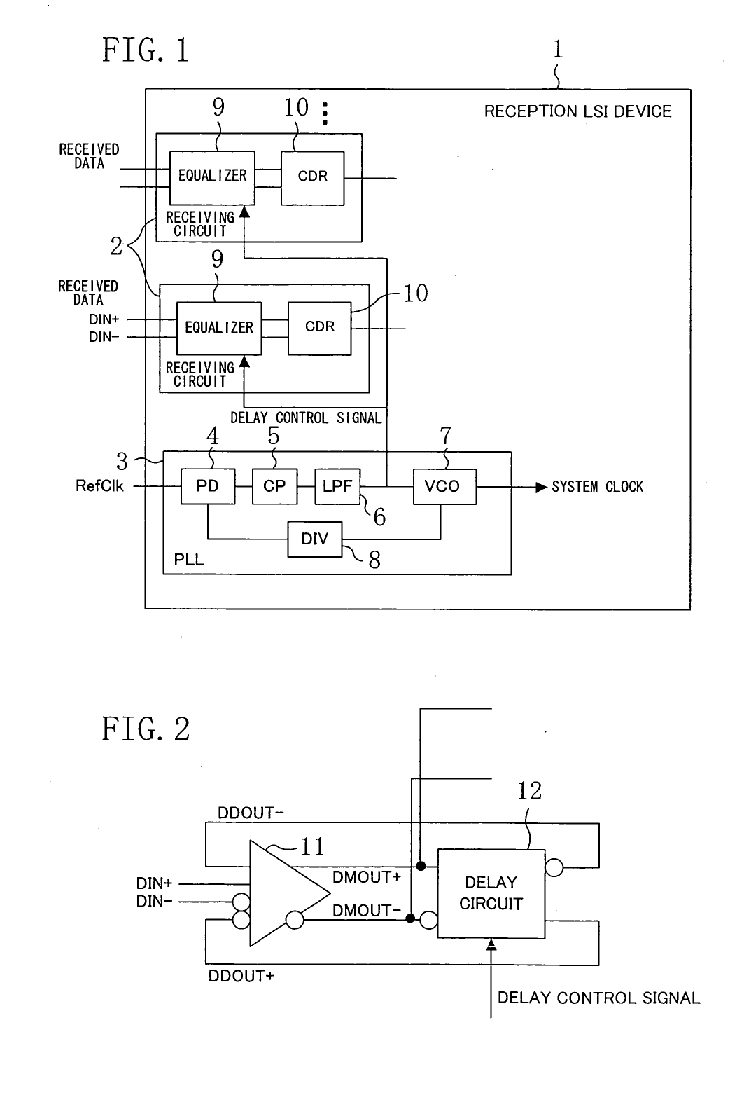

FIG. 1 shows the general structure of a reception LSI device according to embodiment 1 of the present invention. The reception LSI device 1 includes receiving circuits 2 and a phase locked loop (PLL) 3.

<Internal Structure of PLL>

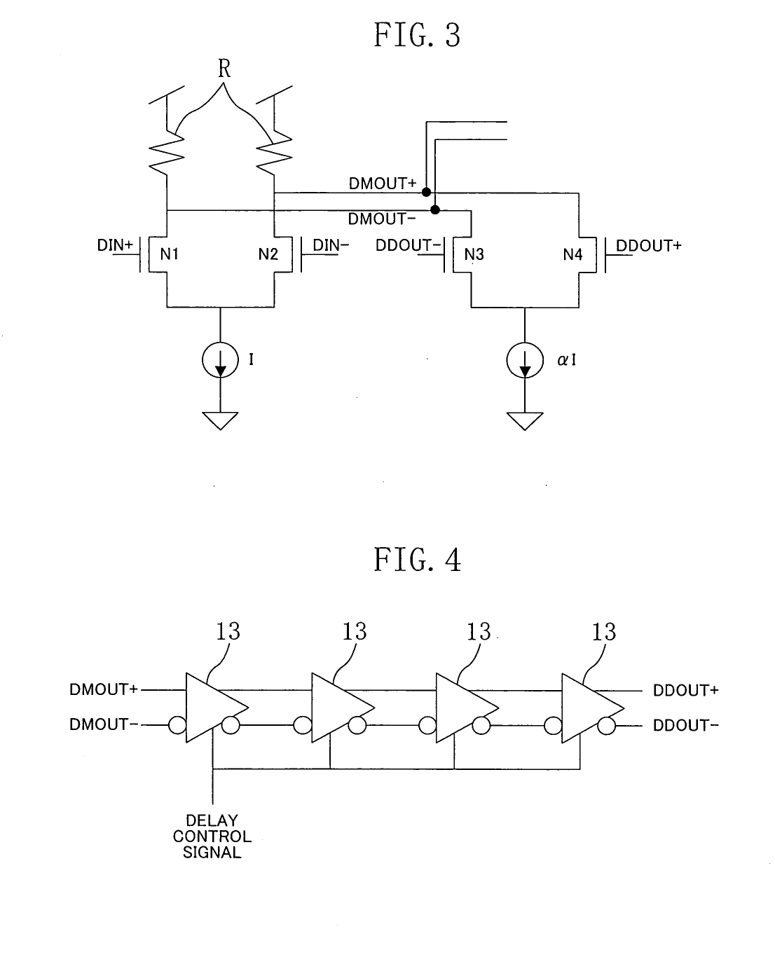

A phase locked loop (PLL) 3 has a structure equivalent to that of an existing PLL and includes a phase detector (PD) 4, a charge pump (CP) 5, a low pass filter (LPF) 6, a voltage controlled oscillator (VCO) 7 and a frequency divider (DIV) 8. The voltage controlled oscillator (VCO) 7 includes a plurality of delay elements connected in a ring arrangement. The phase detector (PD) 4 compares a clock output from the frequency divider (DIV) 8 with reference clock RefClk to output an error signal according to a result of the comparison. The charge pump (CP) 5 outputs a voltage according to the error signal output from the phase detector (PD) 4. The low pass filter (LPF) 6 removes high frequency components of the voltage output from the charge pump (CP) 5 to output the remainder as a delay control signal. The delay control signal is supplied to a delay element (not shown) included in the oscillator (VCO) 7 and to a delay element 13 (see FIG. 3) of an analog delay circuit 12 included in an analog equalizer 9. The delay element of the oscillator (VCO) 7 changes the amount of delay (delay amount) based on the delay control signal output from the low pass filter (LPF) 6 to generate a clock for data reception and a system clock. The frequency divider (DIV) 8 divides the frequency of the clock output from the oscillator (VCO) 7 and outputs the frequency-divided clock to the phase detector (PD) 4.

<Internal Structure of Receiving Circuit 2>

The receiving circuit 2 includes an analog equalizer 9 and a clock data recovery circuit (CDR) 10. The analog equalizer 9 equalizes a received signal based on the delay control signal output from the low pass filter (LPF) 6 included in the phase locked loop (PLL) 3. The clock data recovery circuit (CDR) 10 captures data from a differential signal output from the analog equalizer 9.

<Internal Structure of Analog Equalizer 9>

FIG. 2 shows the internal structure of the analog equalizer 9. The analog equalizer 9 includes a mixer 11 and an analog delay circuit 12. The mixer 11 receives input differential signal DIN+, DIN− and delayed differential signal DDOUT+, DDOUT−from the analog delay circuit 12 and mixes these differential signals to output mixed differential signal DMOUT+, DMOUT−. The analog delay circuit 12 delays mixed differential signal DMOUT+, DMOUT−output from the mixer 11 by a delay amount determined according to the delay control signal and outputs the delayed mixed differential signal as delayed differential signal DDOUT+, DDOUT−.

<Internal Structure of Mixer 11>

FIG. 3 shows the internal structure of the mixer 11. The mixer 11 includes a commonly-employed resistive load operational amplifier and another pair of differential input stages. The mixer 11 includes MOS transistors N1-N4, a load resistor R, and current sources I and αI. The gates of the MOS transistors N1 and N2 receive differential signal DIN+, DIN−. The gates of the MOS transistors N3 and N4 are supplied with delayed differential signal DDOUT−, DDOUT+. Differential output signal DMOUT+, DMOUT−is output according to potential difference ΔVDIN (“VDIN+”−“VDIN−”) of differential signal DIN+, DIN− and potential difference ΔVDDOUT (“VDDOUT+”−“VDDOUT−”) of differential signal DDOUT+, DDOUT−. The intensity of the differential signal inputs which acts on the differential output signals is adjustable by changing current ratio α between current the current sources I and al. In this exemplary circuit, the relationship between the input signals and the output signals is simply represented by “VDMOUT+”−“VDMOUT−”=A×(ΔVDIN-α×ΔVDDOUT). Herein, “A” denotes the gain of the mixer, which is determined based on the current I, the load resistor R and the characteristics of the MOS transistors N1-N4

<Internal Structure of Analog Delay Circuit 12>

FIG. 4 shows the internal structure of the analog delay circuit 12. The analog delay circuit 12 includes a plurality of cascade-connected delay elements 13 (herein, 4 stages of delay elements 13). The delay elements 13 delay mixed differential signal DMOUT+, DMOUT−output from the mixer 11 by the delay amount determined according to the delay control signal output from the low pass filter (LPF) 6 included in the phase locked loop (PLL) 3. The delay elements 13 have the same characteristics as those of the delay elements that constitute the oscillator (VCO) 7. That is, both of these delay elements (the delay elements 13 and the delay elements of the oscillator (VCO) 7) have an equal delay amount which corresponds to the delay control signal. With such a structure, the analog delay circuit 12 is capable of readily setting the delay amount according to the delay control signal.

<Operation of Analog Equalizer 9>

The operation of the analog equalizer 9 included in the reception LSI device shown in FIG. 1 is now described.

Reference clock RefClk generated by a quartz oscillator (not shown), or the like, is input to the phase locked loop (PLL) 3 (see FIG. 1). Reference clock RefClk corresponds to the data rate of the received data and has a rate which is a 1/M of the data rate of the received data (M is arbitrary). In the phase locked loop (PLL) 3, a delay control signal is generated through the phase detector (PD) 4, the charge pump (CP) 5 and the low pass filter (LPF) 6 and output to the delay elements (not shown) included in the oscillator (VCO) 7 and the delay elements of the analog delay circuit 12 included in the analog equalizer 9 (see FIG. 4). Then, the oscillator (see FIG. 1) receives the delay control signal and generates a clock for data reception and a system clock.

On the other hand, in the mixer 11 (see FIG. 2) included in the analog equalizer 9, input differential signal DIN+, DIN− is input to corresponding MOS transistors N1 and N2 (see FIG. 3), and mixed differential signal DMOUT+, DMOUT−is output.

The delay elements included in the analog delay circuit 12 (see FIG. 4) receive the delay control signal output from the low pass filter (LPF) 6 included in the phase locked loop (PLL) 3 and delay mixed differential signal DMOUT+, DMOUT− to output delayed differential signal DDOUT+, DDOUT−. The delay amount set by the analog delay circuit 12 (see FIG. 2) is the minimum data unit represented by input differential signal DIN+, DIN−. That is, mixed differential signal DMOUT+, DMOUT−is delayed by the minimum one of the intervals of level transition (e.g., transition from Low level to High level), i.e., the interval between contiguous level transitions. In embodiment 1, it is assumed that the minimum data interval is 1 bit, and the delay amount of the analog delay circuit 12 is also 1 bit.

Delayed differential signal DDOUT+, DDOUT−obtained by the analog delay circuit 12 (see FIG. 2) is input to the MOS transistors N4 and N3 of the mixer 11 (see FIG. 3). Input differential signal DIN+, DIN− is input to the MOS transistors N1 and N2 (see FIG. 3). As a result, input signal DIN+ and delayed signal DDOUT−are added together and output as mixed signal DMOUT+. Input signal DIN− and delayed signal DDOUT+are added together and output as mixed signal DMOUT−. In this way, input differential signal DIN+, DIN− and a signal obtained by delaying input differential signal DIN+, DIN− by 1 bit and inverting the delayed signal (delayed differential signal DDOUT−DDOUT+) are added together, whereby a signal from which an effect of an amplitude that exists before input differential signal DIN+, DIN− has been removed (mixed differential signal DMOUT+, DMOUT−) is output. In the case where the polarity of the amplitude of input differential signal DIN+, DIN− ((DIN+)−(DIN−)) is equal to that of delayed differential signal DDOUT−, DDOUT+((DDOUT−)−(DDOUT+)), the output amplitude of mixed differential signal DMOUT+, DMOUT−output from the mixer 11 ((DMOUT+)−(DMOUT−)) is larger than that obtained when only input differential signal DIN+, DIN− are input. In the case where the polarity of the amplitude of input differential signal DIN+, DIN− is different from that of delayed differential signal DDOUT−, DDOUT+, the amplitude of mixed differential signal DMOUT+, DMOUT−output from the mixer 11 is smaller than the output amplitude obtained when only input differential signal DIN+, DIN− is input.

Mixed differential signal DMOUT+, DMOUT−obtained by the mixer 11 (see FIG. 2) is further output to the analog delay circuit 12 (see FIG. 2) and the clock data recovery circuit (CDR) 10 (see FIG. 1).

<Variation of Differential Signal>

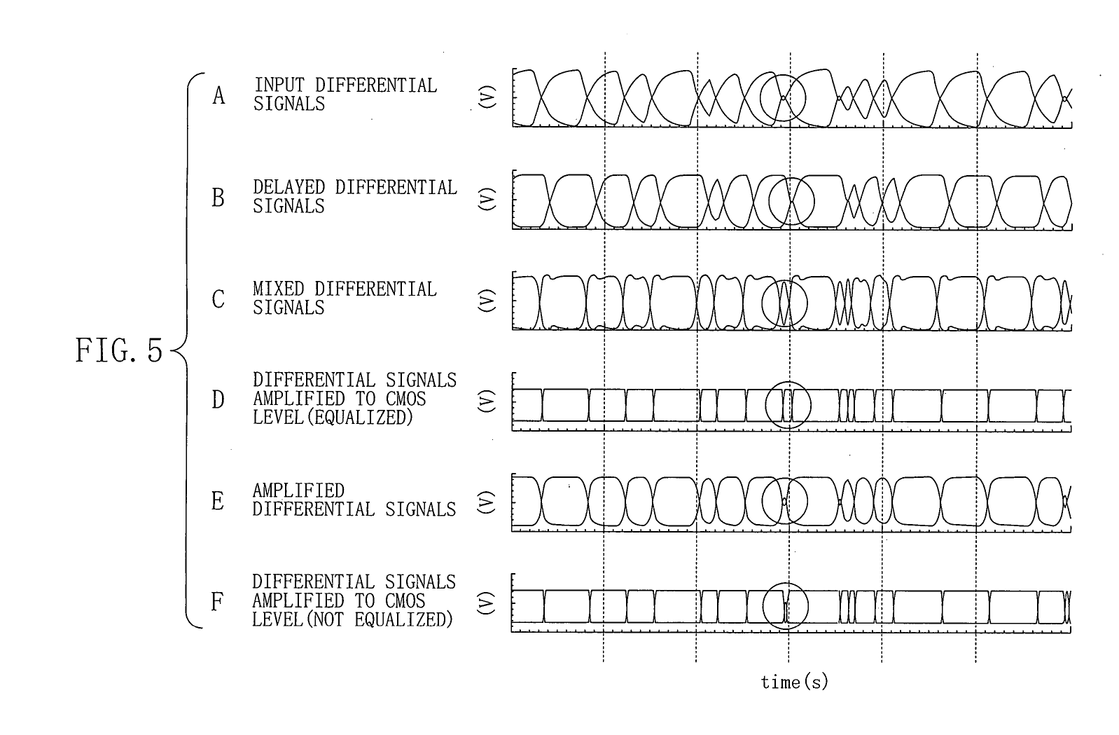

An example of the variation of input differential signal DIN+, DIN− in the above process is described with reference to FIG. 5.

The mixer 11 mixes input differential signal DIN+, DIN− (FIG. 5A) and delayed differential signal DDOUT+, DDOUT−(FIG. 5B) to output mixed differential signal DMOUT+, DMOUT−(FIG. 5C). Now, a case where the above-described process is performed on input differential signal DIN+, DIN− and a case where the above-described process is not performed on input differential signal DIN+, DIN− are compared with reference to FIGS. 5C and 5E.

FIG. 5E shows a differential signal obtained by amplifying the amplitude of input differential signal DIN+, DIN− to a level equal to the amplitude of mixed differential signal DMOUT+, DMOUT−output from the mixer 11 without performing the above-described process. Comparing encircled portions of the signals of FIGS. 5C and 5E, it is seen that the amplitude remains small when the above-described process is not performed (FIG. 5E) while the amplitude is increased when the above-described process is performed (FIG. 5C). Comparing the differential signals of FIGS. 5D and 5F which are obtained by amplifying the amplitude of the differential signals of FIGS. 5C and 5E to a CMOS level, the difference is clearer. Receiving the differential signal of FIG. 5F which has not been subjected to the above-described process, a device at a subsequent stage (e.g., a digital device, or the like) cannot detect the amplitude at the encircled portion. However, in the case where the differential signal of FIG. 5D which has been subjected to the above-described process is input to the device at the subsequent stage, the amplitude of the encircled portion can be detected.

In this way, equalization is achieved by the above-described process.

<Effects>

As described above, the delay elements 13 included in the analog delay circuit 12 delay mixed differential signal DMOUT+, DMOUT−by the delay amount corresponding to the delay control signal output from the low pass filter (LPF) 6 included in the phase locked loop (PLL) 3. The delay elements 13 included in the analog delay circuit 12 have the same characteristics as those of the delay elements of the oscillator (VCO) 7 included in the phase locked loop (PLL) 3. With such a structure, the IIR filter-type (feedback-type) analog equalizer 9 can be realized wherein the delay amount in the analog delay circuit 12 can be readily set, and thus, input differential signal DIN+, DIN−can be continually delayed while the amplitude information of input differential signal DIN+, DIN− is retained.

Further, since it is possible to adjust the magnitudes of the currents (I and αI) output from the current sources I and αI, the mixing ratio of input differential signal DIN+, DIN− and mixed differential signal DMOUT+, DMOUT−can be adjusted. With this structure, the influence of delayed differential signal DDOUT+, DDOUT−output from the analog delay circuit 12 on input differential signal DIN+, DIN− can be adjusted.

In general, the rate of reference clock RefClk is equal to a 1/M of the data rate of the received data (M is arbitrary). The data rate is defined in advance based on the standards, or the like. Thus, it is easy to set reference clock RefClk so as to correspond to the data rate. That is, in the analog delay circuit 12, it is easy to set the delay amount so as to correspond to the data rate of the received data. Even if a phase shift occurs between the data rate and the delay amount, the phase difference can be corrected as in a phase locked loop (PLL).

The phase locked loop (PLL) 3 is used to adjust the delay amount of the analog delay circuit 12, whereby the circuit size can be suppressed.

It is possible that a plurality of analog equalizers 9 having different numbers of delay elements 13 are provided for supporting different data rates. Alternatively, it is possible that the number of delay elements 13 included in the analog equalizer 9 is changed. With this structure, it is possible to perform an equalizing process even with different data rates.

Although the analog equalizer 9 of embodiment 1 has a 2-TAP structure, the number of TAPs can be increased by increasing the number of input nodes of the mixer 11 such that the number of steps of the analog delay circuit 12 is increased.

The delay elements 13 of the analog delay circuit 12 and the delay elements of the oscillator do not need to have the same characteristics. In embodiment 1, the characteristics of the delay elements of the analog delay circuit 12 and the oscillator are the same simply for the purpose of readily setting the delay amount corresponding to the delay control signal. That is, the characteristics of the delay elements may be different so long as the relationship between the delay control signal and the delay amount of the delay element 13 is determined.

The delay amount set by the analog delay circuit 12 becomes closer to the delay amount set by the delay element included in the oscillator (VCO) 7 by adjusting mixed differential signal DMOUT+, DMOUT−input to the analog delay circuit 12 and delayed differential signal DDOUT+, DDOUT−output from the analog delay circuit 12 to have the same amplitude. With this structure, it is possible to set the delay amount of the analog delay circuit 12 more readily.

In the mixer 11, an offset may be added to the delay control signal. With this structure, a phase difference caused by a difference in the set position between input signal DIN+ and delayed signal DDOUT−can be corrected.

In the example described in embodiment 1, the PLL 3 is used. However, the above-described effects of embodiment 1 are also achieved in a system that uses a DLL, or the like. Next, an example which uses a DLL is described with reference to FIG. 9. A DLL 23 includes a phase detector (PD) 4, a charge pump (CP) 5, a low pass filter (LPF) 6, and a voltage controlled delay circuit (VCD) 27. The voltage controlled delay circuit (VCD) 27 includes a plurality of delay elements connected in series as shown in FIG. 4. The phase detector (PD) 4 compares a clock output from the voltage controlled delay circuit (VCD) 27 with reference clock RefClk to output an error signal according to a result of the comparison. The charge pump (CP) 5 and the low pass filter (LPF) 6 are the same as those illustrated in FIG. 1. The delay element of the voltage controlled delay circuit (VCD) 27 changes the amount of delay (delay amount) based on the delay control signal output from the low pass filter (LPF) 6. With this structure, a clock for data reception and a system clock are generated from reference clock RefClk by the voltage controlled delay circuit (VCD) 27. The delay elements 13 included in the analog delay circuit 12 have the same characteristics as those of the delay elements of the voltage controlled delay circuit (VCD) 27 included in the DLL 23. With this structure, the delay amount of the analog delay circuit 12 can be set readily.

In embodiment 1, the phase locked loop (PLL) 3 is used for adjusting the delay amount of the analog delay circuit 12, whereby the circuit size can be suppressed. However, it is also possible to adjust the delay amount using a delay adjustment section exclusively provided for an analog equalizer without using the phase locked loop (PLL) 3.

(Embodiment 2)

<General Structure of Reception LSI Device>

The general structure of a reception LSI device according to embodiment 2 of the present invention is the same as that of embodiment 1 except that the internal structure of the analog equalizer 9 is different.

<Internal Structure of analog Equalizer 9>

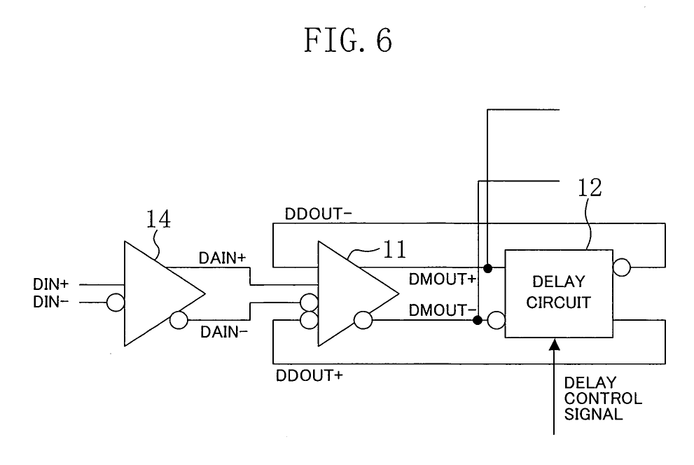

FIG. 6 shows the internal structure of the analog equalizer 9 included in the reception LSI device. The analog equalizer 9 shown in FIG. 6 includes an amplifier 14 in addition to the components of the analog equalizer 9 shown in FIG. 2. The amplifier 14 amplifies the amplitude of input differential signal DIN+, DIN− such that the amplitude of input differential signal DIN+, DIN− is equal to that of delayed differential signal DDOUT+, DDOUT− and outputs the amplified signals as amplified input differential signal DAIN+, DAIN−. The mixer 11 mixes amplified input differential signal DAIN+, DAIN−output from the amplifier 14 and delayed differential signal DDOUT+, DDOUT−output from the analog delay circuit 12 and outputs the mixed signals as mixed differential signal DMOUT+, DMOUT−.

<Effects>

As described above, the differential signal input to the mixer 11 (amplified input differential signal DAIN+, DAIN− and delayed differential signal DDOUT+, DDOUT−) have the same amplitude. Thus, it is possible to readily adjust the mixture ratio of these signals. That is, the equalizing power of the equalizer can be adjusted.

(Embodiment 3)

<General Structure of Reception LSI Device>

The general structure of a reception LSI device according to embodiment 3 of the present invention is the same as that of embodiment 1 except that the internal structure of the analog equalizer 9 is different. Specifically, the analog equalizer 9 of embodiment 3 is different from the analog equalizer 9 of embodiment 1 in the arrangement of the mixer 11 and the delay circuit.

<Internal Structure of Analog Equalizer 9>

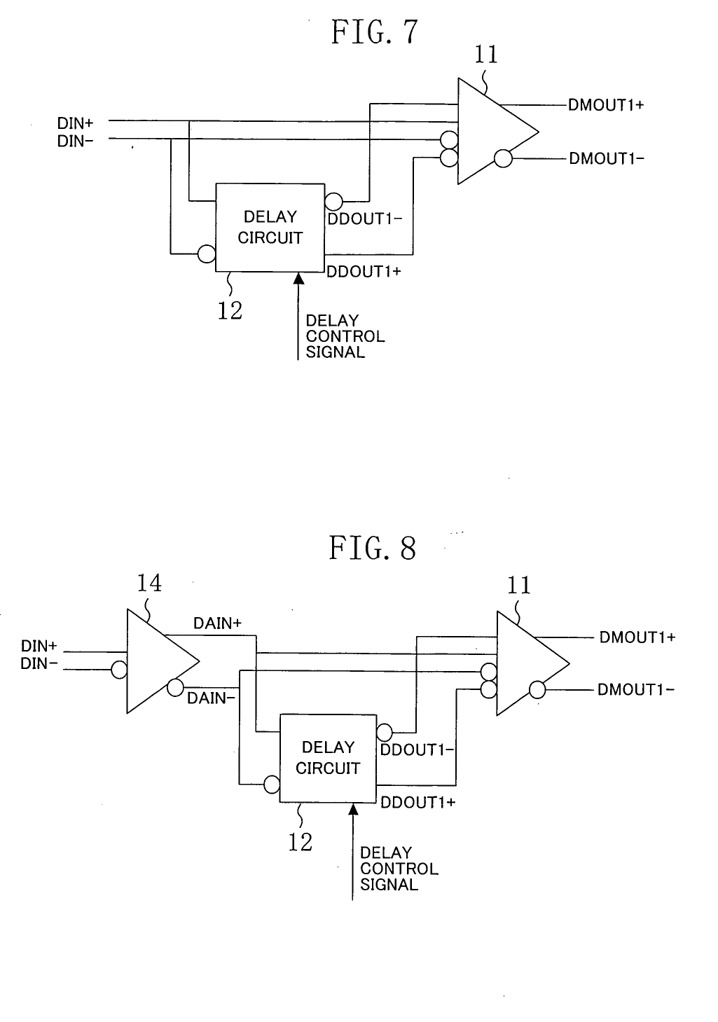

FIG. 7 shows the internal structure of the analog equalizer 9 of embodiment 3.

The analog equalizer 9 includes the mixer 11 and the analog delay circuit 12 as in embodiment 1. The arrangement of the circuit is a FIR filter type arrangement as shown in FIG. 7.

<Operation of Analog Equalizer 9>

The operation of the analog equalizer 9 shown in FIG. 7 is described.

Reference clock RefClk generated by a quartz oscillator (not shown), or the like, is input to the phase locked loop (PLL) 3 (see FIG. 1). In the phase locked loop (PLL) 3, a delay control signal is generated through the phase detector (PD) 4, the charge pump (CP) 5 and the low pass filter (LPF) 6 and output to the delay elements (not shown) included in the oscillator (VCO) 7 and the delay elements (see FIG. 4) of the analog delay circuit 12 (see FIG. 7) included in the analog equalizer 9. Then, the oscillator (see FIG. 1) receives the delay control signal and generates a clock for data reception and a system clock.

On the other hand, the delay elements (see FIG. 4) included in the analog delay circuit 12 (see FIG. 7) delay input differential signal DIN+, DIN− according to the delay control signal received from the low pass filter (LPF) 6 (see FIG. 1) included in the phase locked loop (PLL) 3 and output the delayed signals as delayed differential signal DDOUT1+, DDOUT1−.

Delayed differential signal DDOUT1+, DDOUT1−generated by the analog delay circuit 12 (see FIG. 7) are respectively input to the MOS transistors N1 and N2 (see FIG. 3) of the mixer 11. Input differential signal DIN+, DIN− is also input to the MOS transistors N1 and N2 (see FIG. 3). As a result, input signal DIN+ and delayed signal DDOUT1+are added together, and the resultant signal is output as mixed signal DMOUT1+. Input signal DIN− and delayed signal DDOUT1−are added together, and the resultant signal is output as mixed signal DMOUT1−. In the case where the polarity of the amplitude of input differential signal DIN+, DIN− ((DIN+)−(DIN−)) is equal to that of delayed differential signal DDOUT1−, DDOUT1+((DDOUT1−)−(DDOUT1+)), the output amplitude of mixed differential signal DMOUT1+, DMOUT1− output from the mixer 11 ((DMOUT1+)−(DMOUT1−)) is larger than that obtained when only input differential signal DIN+, DIN− are input. In the case where the polarity of the amplitude of input differential signal DIN+, DIN− is different from that of delayed differential signal DDOUT1+, DDOUT1−, the amplitude of mixed differential signal DMOUT1+, DMOUT1− output from the mixer 11 is smaller than the output amplitude obtained when only input differential signal DIN+, DIN− are input.

Delayed differential signal DDOUT+, DDOUT−generated by the mixer 11 (see FIG. 7) is output to the analog delay circuit 12 (see FIG. 7) and the clock recovery circuit (CDR) (see FIG. 1).

<Effects>

As described above, the delay elements included in the analog delay circuit 12 delay input differential signal DIN+, DIN− by the delay amount corresponding to the delay control signal output from the low pass filter (LPF) included in the phase locked loop (PLL) 3. The delay elements included in the analog delay circuit 12 have the same characteristics as those of the delay elements of the oscillator (VCO) 7 included in the phase locked loop (PLL) 3. With this structure, the delay amount of the analog delay circuit 12 can be set readily.

(Embodiment 4)

<General Structure of Reception LSI Device>

The general structure of a reception LSI device according to embodiment 4 of the present invention is the same as that of embodiment 3 except that the internal structure of the analog equalizer 9 is different.

<Internal Structure of Analog Equalizer 9>

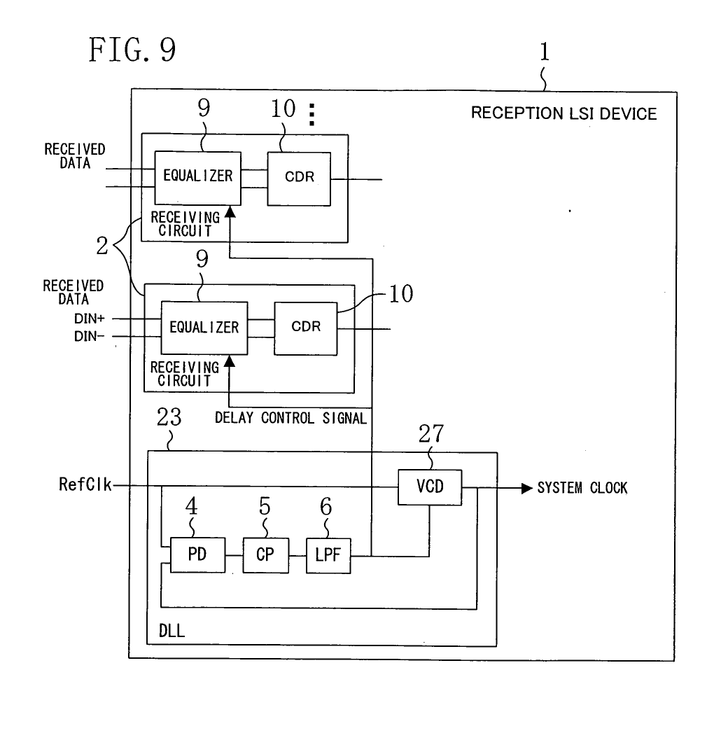

FIG. 8 shows the internal structure of the analog equalizer 9 included in the reception LSI device of embodiment 4. The analog equalizer 9 shown in FIG. 8 includes an amplifier 14 in addition to the components of the analog equalizer 9 shown in FIG. 7. The amplifier 14 amplifies the amplitude of input differential signal DIN+, DIN− such that the amplitude of input differential signal DIN+, DIN− is equal to that of delayed differential signal DDOUT+, DDOUT−output from the analog delay circuit 12 and outputs the amplified signals as amplified input differential signal DAIN+, DAIN−. The mixer 11 mixes amplified input differential signal DAIN+, DAIN−output from the amplifier 14 and delayed differential signal DDOUT1+, DDOUT1−output from the analog delay circuit 12 and outputs the mixed signals as mixed differential signal DMOUT1+, DMOUT1−.

<Effects>

As described above, the differential signals input to the mixer 11 (amplified input differential signal DAIN+, DAIN− and delayed differential signal DDOUT1+, DDOUT1−) have the same amplitude. Thus, it is possible to readily adjust the mixture ratio of these signals.

In the analog equalizer of the present invention, the delay amount can be readily set. Therefore, this analog equalizer is useful to a device that receives an electric, signal transmitted through a cable, or the like.

1. An analog equalizer comprising a mixer and an analog delay circuit, wherein:
the mixer mixes an input signal and a delayed signal output from the analog delay circuit to output a mixed signal; and
the analog delay circuit delays the mixed signal output from the mixer to output a delayed signal.

2. The analog equalizer of claim 1, further comprising a delay control section for controlling a delay amount of the analog delay circuit.

3. The analog equalizer of claim 2, wherein:
the delay control section outputs a delay control signal according to a predetermined clock; and
the analog delay circuit controls the delay amount according to the delay control signal output from the delay control section.

4. The analog equalizer of claim 3, wherein:
the delay control section includes a PLL circuit;
the PLL circuit includes a delay control signal output section and a voltage controlled oscillator;
the delay control signal output section outputs the delay control signal according to a frequency difference or phase difference between the predetermined clock and a clock output from the voltage controlled oscillator;
the voltage controlled oscillator adjusts the delay amount according to the delay control signal output from the delay control signal output section to output a clock; and
the delay amount of the analog delay circuit corresponds to the delay amount of the voltage controlled oscillator.

5. The analog equalizer of claim 4, further comprising a matching circuit for matching the amplitude of a signal input to the analog delay circuit and the amplitude of a signal output from the analog delay circuit.

6. The analog equalizer of claim 3, wherein:
the delay control section includes a DLL circuit;
the DLL circuit includes a delay control signal output section and a voltage controlled delay circuit;
the delay control signal output section outputs the delay control signal according to a phase difference between the predetermined clock and a clock output from the voltage controlled delay circuit;
the voltage controlled delay circuit delays the predetermined clock by the delay amount determined according to the delay control signal output from the delay control signal output section; and
the delay amount of the analog delay circuit corresponds to the delay amount of the voltage controlled delay circuit.

7. The analog equalizer of claim 6, further comprising a matching circuit for matching the amplitude of a signal input to the analog delay circuit and the amplitude of a signal output from the analog delay circuit.

8. The analog equalizer of claim 7, further comprising a matching circuit for matching the amplitudes of signals input to the mixer.

9. An analog equalizer, comprising:
an analog delay circuit for delaying an input signal to output a delayed signal; and
a mixer for mixing the input signal and the delayed signal output from the analog delay circuit.

10. The analog equalizer of claim 9, further comprising a delay control section for controlling a delay amount of the analog delay circuit.

11. The analog equalizer of claim 10, wherein:
the delay control section outputs a delay control signal according to a predetermined clock; and
the analog delay circuit controls the delay amount according to the delay control signal output from the delay control section.

12. The analog equalizer of claim 11, wherein:
the delay control section includes a PLL circuit;
the PLL circuit includes a delay control signal output section and a voltage controlled oscillator;
the delay control signal output section outputs the delay control signal according to a frequency difference or phase difference between the predetermined clock and a clock output from the voltage controlled oscillator;
the voltage controlled oscillator adjusts the delay amount according to the delay control signal output from the delay control signal output section to output a clock; and
the delay amount of the analog delay circuit corresponds to the delay amount of the voltage controlled oscillator.

13. The analog equalizer of claim 12, further comprising a matching circuit for matching the amplitude of a signal input to the analog delay circuit and the amplitude of a signal output from the analog delay circuit.

14. The analog equalizer of claim 11, wherein:
the delay control section includes a DLL circuit;
the DLL circuit includes a delay control signal output section and a voltage controlled delay circuit;
the delay control signal output section outputs the delay control signal according to a phase difference between the predetermined clock and a clock output from the voltage controlled delay circuit;
the voltage controlled delay circuit delays the predetermined clock by the delay amount determined according to the delay control signal output from the delay control signal output section; and
the delay amount of the analog delay circuit corresponds to the delay amount of the voltage controlled delay circuit.

15. The analog equalizer of claim 14, further comprising a matching circuit for matching the amplitude of a signal input to the analog delay circuit and the amplitude of a signal output from the analog delay circuit.

16. The analog equalizer of claim 15, further comprising a matching circuit for matching the amplitudes of signals input to the mixer.
